(19) United States
(12) Patent Application Publication
(10) Pub. No.: US 2026/0020349 A1
(43) Pub. Date: Jan. 15, 2026

(54) ESD PROTECTION DEVICE WITH SELF-ALINGED TRIGGER REGIONS

(71) Applicant: Infineon Technologies AG, Neubiberg (DE)

(72) Inventors: Vadim Valentinovic Vendt, Ottobrunn (DE); Juliane Laurer, Regensburg (DE); Egle Tylaite, München (DE); Isabella Götz, Bodenwöhr (DE); Max Stelzer, Regensburg (DE); Bastian Birkner, Regensburg (DE)

(21) Appl. No.: 19/266,300

(22) Filed: Jul. 11, 2025

Related U.S. Application Data
(60) Provisional application No. 63/670,209, filed on Jul. 12, 2024.

(51) Int. Cl. H10D 89/60; H01L 21/033; H01L 21/266; H10D 8/01; H10D 8/20; H10D 62/10; H10D 62/83

(52) U.S. Cl. CPC H10D 89/611; H01L 21/0337; H01L 21/266; H10D 8/024; H10D 8/20; H10D 62/126; H10D 62/83

(57) ABSTRACT

A method of forming a semiconductor device includes forming a row of n-type wells and p-type wells in an upper surface of a semiconductor body, the p-type wells arranged alternatingly with the n-type wells, forming trigger regions in between the n-type wells and the p-type wells, the trigger regions including a low-doped section of the semiconductor body that is configured to induce current flow between the p-type wells and the n-type wells via avalanche breakdown, wherein the p-type wells and the n-type wells are formed by implanting dopant atoms into the upper surface of the semiconductor body, and wherein the low-doped section of the semiconductor body is formed by a hardmask that prevents the dopant atoms from penetrating the upper surface of the semiconductor body during the implanting of the dopant atoms.

### TECHNICAL FIELD

The instant application relates to semiconductor devices, and more particularly to electrostatic discharge protection devices.

### BACKGROUND

Components such as transistors, diodes, resistors, electro-optical devices, precision film resistors and a variety of integrated circuits are all sensitive to electrostatic discharge (ESD). As electronics manufacturers drive to miniaturize devices and improve operating speeds, susceptibility of devices to ESD is increasing. For avoiding damage to integrated circuits or electronic devices by pulses during assembly or operation, ESD protection devices are connected between pins of an integrated circuit or between traces on a printed circuit board to prevent a malfunction or breakdown of circuits connected between the pins or traces by ESD current pulses. ESD protection devices are configured to be non-conductive at normal operational levels and become conductive in the presence of an overvoltage from an ESD event to divert damaging current from sensitive elements.

One type of ESD protection device is a so-called silicon-controlled rectifier. This device is formed by four doped regions that successively alternate with one another. Silicon controlled rectifier devices can include trigger mechanisms that are configured to place the device into conduction mode at predetermined voltages. It is desirable to form trigger mechanisms in silicon-controlled rectifier devices with precisely controllable trigger voltages so that the boundaries of the conduction range are well-defined.

### SUMMARY

Those skilled in the art will recognize additional features and advantages upon reading the following detailed description, and upon viewing the accompanying drawings.

A method of forming a semiconductor device is disclosed. According to an embodiment, the method comprises forming a row of n-type wells and p-type wells in an upper surface of a semiconductor body, the p-type wells arranged alternatingly with the n-type wells along a first direction of the semiconductor body, forming trigger regions in between the n-type wells and the p-type wells, the trigger regions comprising a low-doped section of the semiconductor body that is configured to induce current flow between the n-type wells and the p-type wells via avalanche breakdown, wherein the p-type wells and the n-type wells are formed by implanting dopant atoms into the upper surface of the semiconductor body, and wherein the low-doped section of the semiconductor body is formed by a hardmask that prevents the dopant atoms from penetrating the upper surface of the semiconductor body during the implanting of the dopant atoms.

A semiconductor device is disclosed. According to an embodiment, the semiconductor device comprises a row of n-type wells and p-type wells in an upper surface of a semiconductor body, the p-type wells arranged alternatingly with the n-type wells along a first direction of the semiconductor body, trigger regions in between the n-type wells and the p-type wells, the trigger regions comprising a low-doped section of the semiconductor body that is configured to induce current flow between the p-type wells and the n-type wells via avalanche breakdown, and hardmasks disposed over the low-doped sections of the semiconductor body, wherein the hardmasks comprise a first outer edge side and a second outer edge side opposite from the first outer edge side, wherein outer boundaries of the p-type wells are aligned with the first outer edge side the hardmasks, and wherein outer boundaries of the n-type wells are aligned with the second outer edge side the hardmasks.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a plan-view layout of an ESD protection device, according to an embodiment.

FIG. 2, which includes FIGS. 2A and 2B, illustrates cross-sectional views of the ESD protection device of FIG. 1, according to an embodiment. FIG. 2A illustrates a cross-sectional view of the ESD protection device along a plane that is outside a trigger region and FIG. 2B illustrates a cross-sectional view of the ESD protection device along a plane that intersects a trigger region.

FIG. 3, which includes FIGS. 3A and 3B, illustrates close-up views of an ESD protection device, according to an embodiment. FIG. 3A illustrates a plan-view of a trigger region with a hardmask and FIG. 3B illustrates a cross-sectional view of a trigger region with a hardmask disposed over a low-doped region.

FIG. 4, which includes FIGS. 4A and 4B, illustrates close-up views of an ESD protection device, according to an embodiment. FIG. 4A illustrates a plan-view of a region comprising a p-well, an n-well and a trigger region and FIG. 4B illustrates a cross-sectional view of a region comprising a p-well, an n-well and a trigger region.

FIG. 5, which includes FIGS. 5A and 5B, illustrates close-up views of an ESD protection device, according to an embodiment. FIG. 5A illustrates a plan-view of a region comprising a p-well, an n-well and a trigger region and FIG. 5B illustrates a cross-sectional view of a region comprising a p-well, an n-well and a trigger region.

FIG. 6, which includes FIGS. 6A and 6B, illustrates a method for forming a trigger region of an ESD protection device with a hardmask disposed over a lightly doped region, according to an embodiment.

### DETAILED DESCRIPTION

Embodiments of an ESD protection device are disclosed herein. The ESD protection device comprises trigger regions arranged between p-type wells and n-type wells. These trigger regions comprise an unintentionally doped section of the semiconductor body that is configured to induce current flow between the p-type wells and the n-type wells in an overvoltage condition of the device. In this device, the width of the unintentionally doped section of the semiconductor body determines the avalanche breakdown voltage of a triggering diode that induces the ESD protection device in conduction mode. The techniques disclosed herein utilize a hardmask structure to define the boundaries of this intrinsically doped section of the semiconductor body. In comparison to softmask implantation techniques, the hardmask technique greatly reduces the potential variation in well boundaries and consequently facilitates well-controlled trigger voltage.

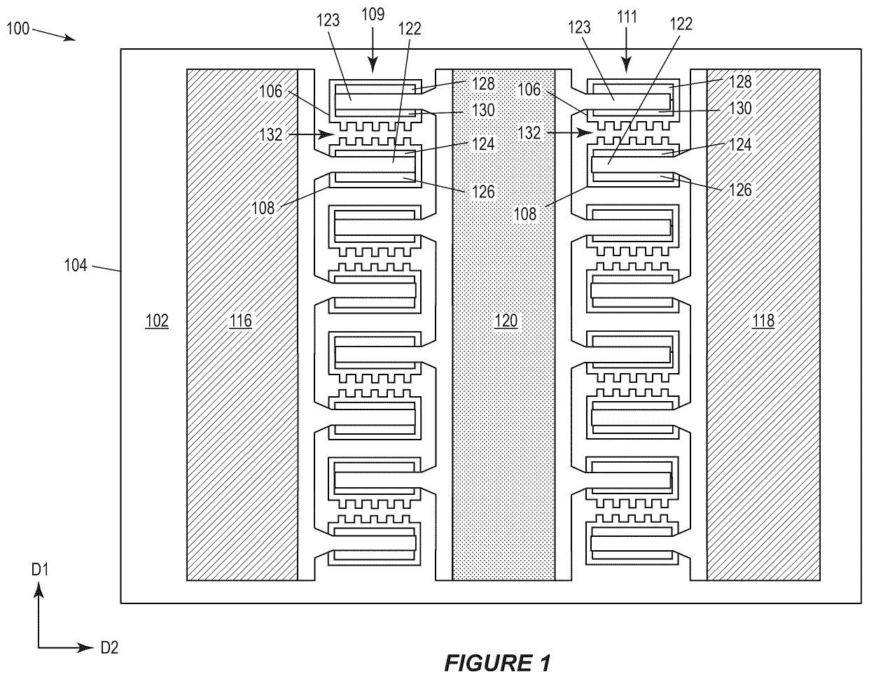

Referring to FIG. 1, an ESD protection device 100 is depicted, according to an embodiment. The ESD protection device 100 is formed in an upper surface 102 of a semiconductor body 104. The semiconductor body 104 may include or consist of a semiconductor material from group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). The semiconductor body 104 may include other active devices, e.g., transistors and in particular power switching devices, e.g., MOSFETs, IGBTs, HEMTs, etc., in addition to the ESD protection device 100. Alternatively, the ESD protection device 100 may be implemented as a discrete device that is configured to protect an external element through external connections, e.g., bond wire connections, PCB connections, etc.

The ESD protection device 100 comprises a plurality of p-type wells 106 and n-type wells 108 formed in the upper surface 102 of the semiconductor body 104. The p-type wells 106 and n-type wells 108 are arranged in rows, wherein the p-type wells 106 and the n-type wells 108 alternate with one another. As shown, the ESD protection device 100 comprises a first row 109 of the p-type wells 106 and n-type wells 108 on the left side of the figure and a second row 111 of the p-type wells 106 and n-type wells 108 on the right side of the figure. In these rows, the p-type wells 106 and the n-type wells 108 alternate with one another along a first direction D1.

According to an embodiment, the ESD protection device 100 is configured such that a unit cell comprising, e.g., one of the p-type wells 106 and half of two of the n-type wells 108 on either side of the p-type well 106 (or vice-versa) has a fixed width, thus allowing for the provision of multiple unit cells being arranged next to one another in a regular spacing. For example, each of these unit cells may have a regular width of between 1.0 μm and 10.0 μm.

The ESD protection device 100 comprises first and second shallow doped zones 124, 126 disposed within each of the n-type wells 108. The first and second shallow doped zones 124, 126 have an opposite conductivity type from one another. The first shallow doped zones 124 are p-type regions that form a p-n junction with the subjacent n-type wells 108 and the second shallow doped zones 126 are n-type regions that are more highly doped than the underlying n-type wells 108. Correspondingly, the ESD protection device 100 comprises third and fourth shallow doped zones 128, 130 disposed within each of the p-type wells 106. The third and fourth shallow doped zones 128, 130 have an opposite conductivity type from one another. The third shallow doped zones 128 are p-type regions that are more highly doped than the underlying p-type wells 106. The fourth shallow doped zones 130 are n-type regions that form a p-n junction with the subjacent p-type wells 106.

The ESD protection device 100 comprises a first contact pad 116, a second contact pad 118 and a central interconnect structure 120. The first contact pad 116 is electrically connected to the n-type wells 108 in the first row 109. The second contact pad 118 is electrically connected to the n-type wells 108 in the second row 111. The central interconnect structure 120 is electrically connected to the p-type wells 106 in the first row 109 and the p-type wells 106 in the second row 111. The first contact pad 116, the second contact pad 118 and the central interconnect structure 120 may each be formed from an electrically conductive material, e.g., copper, aluminum, nickel, and alloys thereof. The conductive runners 122, 123 may likewise be formed from an electrically conductive material, e.g., copper, aluminum, nickel, and alloys thereof, or highly doped polysilicon.

According to an embodiment, the semiconductor body 104 has a background dopant concentration of no greater than 10¹⁵ dopant atoms/cm³ and more typically in the range of 10¹² dopant atoms/cm³ to 10¹⁴ dopant atoms/cm³. The background dopant concentration of the semiconductor body 104 can be a net p-type or a net n-type concentration. The p-type wells 106 and the n-type wells 108 have a higher net dopant concentration than the background dopant concentration of the semiconductor body 104. For example, the n-type wells 108 may have a net n-type dopant concentration of at least 10¹⁵ dopant atoms/cm³ and more typically in the range of 10¹⁷ dopant atoms/cm³. Likewise, the p-type wells 106 may have a net p-type dopant concentration of at least 10¹⁵ dopant atoms/cm³ and more typically in the range of 10¹⁷ dopant atoms/cm³. The first second, third and fourth shallow doped zones 124, 126, 128, 130 have a higher net dopant concentration than the underlying dopant concentration of the n-type wells 108 or the p-type wells 106 that they are formed within. For example, the first and third shallow doped zones 124, 128 may have a net p-type dopant concentration of at least 10¹⁹ dopant atoms/cm³ and more typically in the range of 10¹⁹ dopant atoms/cm³ to 10²¹ dopant atoms/cm³ and the second and fourth shallow doped zones 126, 130 may have a net n-type dopant concentration of at least 10¹⁹ dopant atoms/cm³ and more typically in the range of 10¹⁹ dopant atoms/cm³ to 10²¹ dopant atoms/cm³.

The above-described doped regions of the ESD protection device 100 may be formed using masked implantation techniques. According to an embodiment, the p-type wells 106 are formed by a first implantation process that implants p-type dopants in the semiconductor body 104 and the n-type wells 108 are formed by a second implantation process that implants n-type dopants into the semiconductor body 104. For example, in the case of a semiconductor body 104 formed of silicon, the first implantation process may comprise implanting any one or more of: B, BF, BF₂, Al, etc. into the semiconductor body 104, and the second implantation process may comprise implanting any one or more of: P, As, Bi, etc. into the semiconductor body 104. In this context, the terms “first” and “second” do not denote a particular order. The first, second, third and fourth shallow doped zones 124, 126, 128, 130 may be formed by further implantation processes that are performed after the first and second implantation processes as described above. For example, the first and third shallow doped zones 124, 128 may be formed by a third implantation process that implants p-type dopants into the semiconductor body 104 and the second and fourth shallow doped zones 126, 130 may be formed by a fourth implantation process that implants n-type dopants into the semiconductor body 104. In this context, the terms “third” and “fourth” implantation process do not denote a particular order. The implanted dopant atoms may be activated by annealing steps, which may be performed concurrently after individual implantation processes or after all implantation processes are performed.

The working principle of the ESD protection device 100 is as follows. The ESD protection device 100 is a lateral device, meaning that it is configured to conduct or block a current flowing parallel to the upper surface 102 of the semiconductor body 104. In a conduction mode of the ESD protection device 100, current flows between the first contact pad 116 and the second contact pad 118. A grouping of the n-type wells 108 in the first row 109, the p-type wells 106 in the first row 109, the p-type wells 106 in the second row 111 and the n-type wells 108 in the second row 111 collectively form an PNPN structure between the first contact pad 116 and the second contact pad 118. At one voltage polarity, one of the first and second rows 109, 111 operates in SCR mode, whereas the other one of the first and second rows 109 operates as a forward biased p-i-n diode. At the opposite voltage polarity, the first and second rows 109, 111 operating in SCR mode and p-i-n diode mode switch. As a result of having these two devices arranged in an anti-series configuration, the ESD protection device 100 is symmetric and bidirectional as between the first contact pad 116 and the second contact pad 118. Stated another way, the ESD protection device 100 is a bidirectional device with 2 identical device structures of reversed orientation connected in series with one another. The ESD protection device 100 comprises trigger regions 132 in between one of the p-type wells 106 and one of the n-type wells 108. These trigger regions 132 operate as avalanche diodes that become conductive when an avalanche breakdown condition is reached. Once the device is in the conduction state, a three-dimensional current flows between the n-type wells 108 and the p-type wells 106 within the semiconductor body 104. This concept can be used to form a low-ohmic current path that shunts a sudden and large current, e.g., from an ESD event, away from another device that is connected to the ESD protection device 100.

The ESD protection device 100 may optionally comprise electrical isolation regions formed in the semiconductor body 104 around the n-type wells 108 and the p-type wells 106. For simplicity sake, these electrical isolation regions have been omitted from the figures. These electrical isolation regions may lead to improved device performance by lowering total device capacitance. An example of an ESD protection device with these electrical isolation regions is described in U.S. Pat. No. 11,776,996 to Tylaite, the content of which is described by reference herein in its entirety. In U.S. Pat. No. 11,776,996 to Tylaite, the electrical isolation regions are asymmetric such that the isolating area surrounding the p-type wells is greater than the isolating area surrounding the n-type wells. The ESD protection device 100 may be configured in this way. Alternatively, the ESD protection device 100 may comprise electrical isolation regions with equal isolating areas around the p-type wells and the n-type wells.

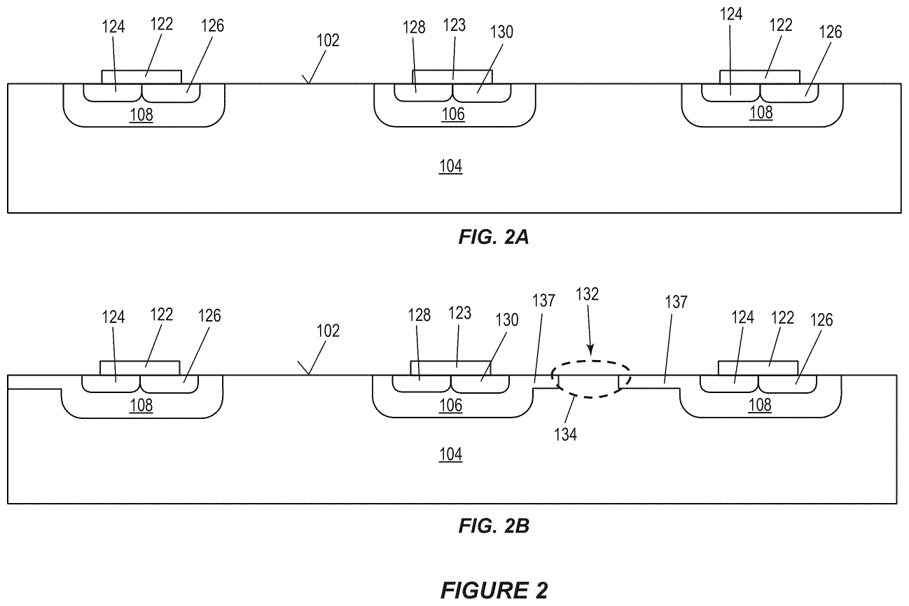

Referring to FIG. 2, the ESD protection device 100 from FIG. 1 is shown from a cross-sectional perspective. FIG. 2A shows the ESD protection device 100 along a cross-section that extends in the first direction D1 and is between one of the trigger regions 132. FIG. 2B shows the ESD protection device 100 along a cross-section that extends in the first direction D1 and intersects one of the trigger regions 132. As shown in FIG. 2B, the trigger regions 132 include a low-doped section 134 of the semiconductor body 104 in between one of the p-type wells 106 and one of the n-type wells 108. The low-doped section 134 of the semiconductor body 104 in the trigger regions 132 corresponds to regions in which the effective distance between the p-type wells 106 and the n-type wells 108 are brought closer to one another, relative to the distance between these wells outside of the trigger regions 132. In the depicted embodiment, the p-type wells 106 and the n-type wells 108 each connect with extension regions 137 that bring this effective distance closer. In other embodiments, trigger regions 132 may be created by forming semiconductor paths in between regions of electrical isolation material. In general, the semiconductor material in the low-doped sections 134 can have any dopant concentration that is lower than that of the p-type wells 106 and the n-type wells 108. As shown, the low-doped sections 134 correspond to a region of intrinsic, i.e., intrinsically doped, material from the semiconductor body 104. Alternatively, the low-doped sections 134 may be provided by lightly intentionally doped regions.

The breakdown voltage VBR of the avalanche diode structure that triggers conduction of the ESD protection device 100 is determined by the width of the low-doped section 134 of the semiconductor body 104 in between the p-type wells 106 and the n-type wells 108. As explained above, the p-type wells 106 and the n-type wells 108 may be formed using implantation techniques. However, these implantation techniques may be imprecise. Specifically, masked implantation techniques in which the boundaries of the p-type wells 106 and the n-type wells 108 are defined by photomask material, i.e., soft-mask material, that is lithographically patterned on the upper surface of the semiconductor body may suffer from misalignment issues. This misalignment may cause the width of the low-doped section 134 of the semiconductor body 104 to vary by at least 50 nm, at least 100 nm, at least 200 nm, at least 300 nm, or more. Consequently, the breakdown voltage VBR of the avalanche diode structure may vary significantly as between different trigger regions 132, different ESD protection devices 100, or lots of ESD protection devices 100. This process variation makes it challenging to design the ESD protection device 100 to meet defined specifications and/or may result in low yields as many non-conforming products must be discarded.

The embodiments disclosed herein allow for improved precision in the breakdown voltage VBR of the avalanche diode structure that triggers conduction of the ESD protection device 100. According to these embodiments, a hardmask 136 (shown in the figures below) is formed on the semiconductor body prior to implantation. This hardmask 136 is used to selectively block dopant atoms during the implantation steps which form the p-type wells 106 and the n-type wells 108 such that outer edge sides of the hardmask 136 define the width of the low-doped section 134 of the semiconductor body 104 in between the p-type wells 106 and the n-type wells 108. Advantageously, the hardmask 136 facilitates much greater precision in the boundaries of the p-type wells 106 and the n-type wells 108 such that the width of the low-doped portion of the semiconductor body 104 is much more precisely controllable. According to the techniques to be described herein, the width variation of the low-doped section 134 of the semiconductor body 104 can be reduced by 30%, 40%, 50% or more in comparison to the previously described masked implantation techniques.

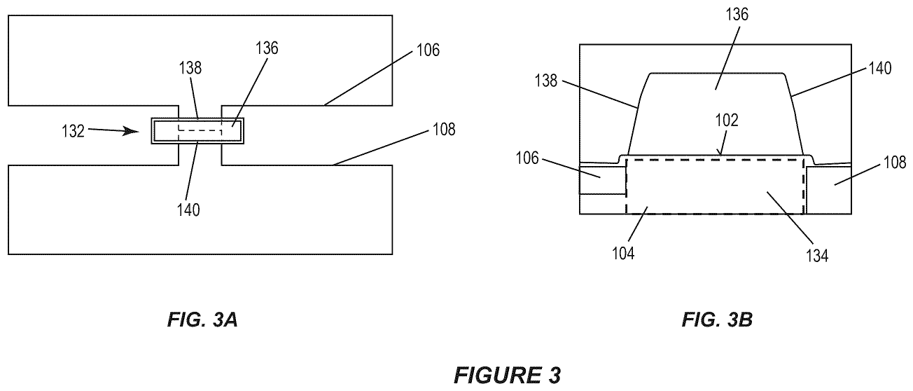

Referring to FIG. 3, an ESD protection device 100 is shown that comprises a hardmask 136 that is formed on the upper surface 102 of the semiconductor body 104. The hardmask 136 is formed before the implantation steps that are used to form the p-type wells 106 and the n-type wells 108. During these implantation steps, the hardmask 136 prevents the dopant atoms from penetrating the upper surface 102 of the semiconductor body 104. The hardmask 136 comprises a first outer edge side 138 and a second outer edge side 140 opposite from the first outer edge side 138. The width of the hardmask 136 between the first and second outer edge sides 138, 140 determines a separation distance between one of the p-type wells 106 and one of the n-type wells 108. Hence, the width of the low-doped section 134 of the semiconductor body 104 is defined by the width of the hardmask 136.

The hardmask 136 may comprise any type of hardmask material. As contrasted with so-called softmask materials, which are photoresist materials that are patterned by UV exposure, hardmask materials refer to materials that are not directly patternable by lithographic exposure. Exemplary materials for the hardmask 136 include semiconductor oxides and nitrides, e.g., SiO₂ (silicon dioxide), SiN (silicon nitride), SiOₓN_{y} (silicon oxynitride), carbon-based hardmasks materials, and metal-based hardmask materials, e.g., TIN, TaN, etc. According to an embodiment, the hardmask 136 is formed by depositing, e.g., by physical vapor deposition, atomic layer deposition, sputtering, etc. a blanket layer of hardmask material, and subsequently patterned by an etching technique, e.g., dry etching or wet chemical etching, to define the first and second outer edge sides 138, 140. According to another embodiment, the hardmask 136 is formed by a LOCOS (local oxidation of silicon) technique. More generally, any type of technique may be used to form a hardmask 136 pattern on the semiconductor substrate.

The hardmask 136 facilitates increased precision in the width of the low-doped section 134 of the semiconductor body 104, i.e., the boundaries between one of the p-type wells 106 and one of the n-type wells 108, at least partly because the first and second outer edge sides 138, 140 of the hardmask 136 can be formed at relatively steep angles. Process parameters, such as thickness of the hardmask 136, composition of the hardmask 136, and structuring technique of the hardmask 136, can be selected such that the first and second outer edge sides 138, 140 are formed at angles of at least 70°, e.g., 75°, 76°, 77°, 78°, 79°, 80° or more, relative to the upper surface 102 of the semiconductor body 104. These relatively steep angles mitigate dispersion of dopant atoms and consequently form precise boundaries for the p-type wells 106 and the n-type wells 108.

In an example of a process for forming the trigger regions 132 of the semiconductor body 104, the hardmask 136 is initially formed on the upper surface 102 of the semiconductor body 104. As shown in FIG. 3A, the hardmask 136 may be formed as a single strip of material locally in the vicinity of the trigger regions 132. Subsequently, the first and second implantation processes as described above are performed to form the p-type wells 106 and the n-type wells 108, respectively. The photomask used to form the p-type wells 106 in the first implantation process is formed to overlap with the hardmask 136 such that the first outer edge side 138 of the hardmask 136 forms a boundary of the implantation window for implanting p-type dopants. Correspondingly, the photomask used to form the n-type wells 108 in the second implantation process is formed to overlap with the hardmask 136 such that the second outer edge side 140 of the hardmask 136 forms a boundary of the implantation window for implanting n-type dopants. The material composition and thickness of the hardmask 136 is selected such that the dopant atoms are at least substantially prevented from entering the semiconductor body through the hardmask 136. As shown in FIG. 3B, the hardmask 136 is disposed over the low-doped section 134 of the semiconductor body 104 with the outer boundaries of the p-type wells 106 aligned with the first outer edge side 138 of the hardmask 136 and the outer boundaries of the n-type wells 108 aligned with the second outer edge side 140 of the hardmask 136. In this way, the hardmask technique disclosed herein results in a self-alignment of the separation distance between the p-type wells 106 and the n-type wells 108 within the trigger regions 132, as it depends only on a single hardmask 136.

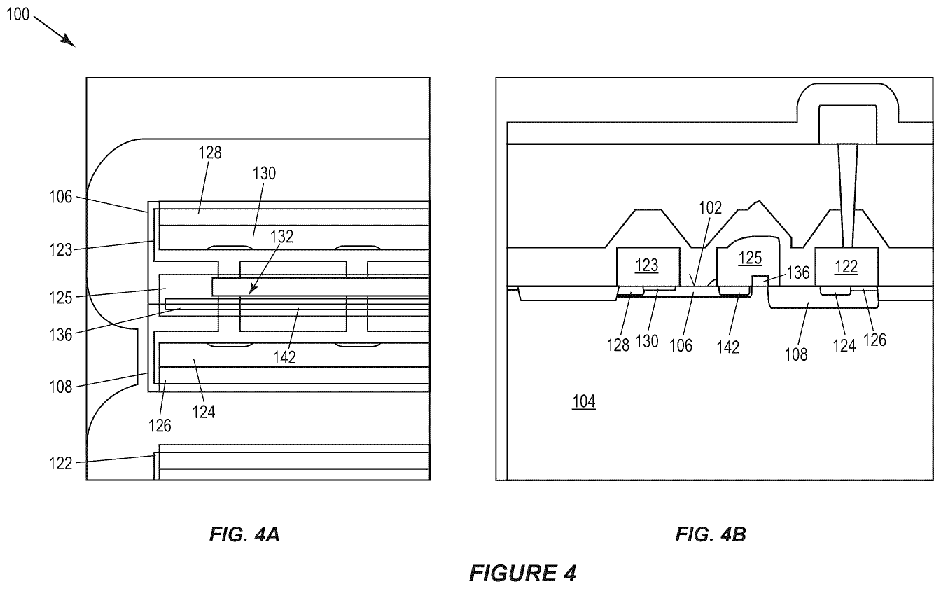

Referring to FIG. 4, an ESD protection device 100 is shown, according to an embodiment. In this embodiment, the ESD protection device 100 comprises a third conductive runner 125 that extends across the trigger regions 132. This third conductive runner 125 can be used to form a secondary well-tap with one of the p-type wells 106 or the n-type wells 108. In the depicted embodiment, the third conductive runner 125 forms a secondary well-tap with one of the p-type wells 106. Alternatively, the third conductive runner 125 may form a similar secondary well-tap with one of the n-type wells 108. As shown in FIG. 4B, a fifth shallow doped zone 142 may be formed within the p-type well 106 to facilitate a low-ohmic connection. The fifth shallow doped zone 142 may be formed in a similar manner as the first and third shallow doped zones 124, 128 as described above. The third conductive runner 125 may be provided in a similar manner and have the same composition as the conductive runners 122, 123 extending over the p-type wells 106 and the n-type wells 108. A common bus line may be connected to each of the third conductive runners 125 that form the secondary well-tap. This may equalize the potential of the doped regions and prevent asynchronous triggering.

As shown in FIG. 4B, the hardmask 136 may remain intact on the upper surface 102 of the semiconductor body 104 after the doping processes. Layers which form the interconnect structure of the ESD protection device 100, i.e., interconnect lines, passivation layers, insulating layers, etc., may be formed around the hardmask 136. In this case, the third conductive runner 125 is formed to envelop the hardmask 136. A thin barrier layer may be formed on the surface of the semiconductor body and over the hardmask 136 to prevent contamination. Additional interlayer dielectrics and upper metallization layers may be formed over the conductive runners 122, 123.

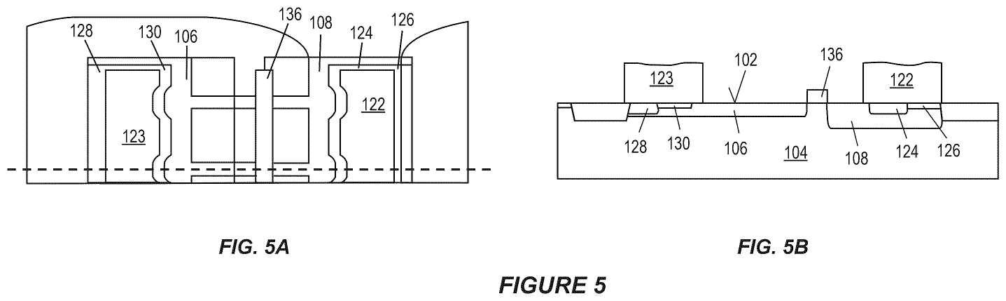

Referring to FIG. 5, an ESD protection device 100 is shown, according to an embodiment. The ESD protection device 100 of FIG. 5 is similar to that of FIG. 4, except that the third conductive runner 125 and secondary well-tap has been omitted from the device. As can be seen, the hardmask 136 may remain intact on the upper surface 102 of the semiconductor body 104 after the doping processes. Additional interlayer dielectrics and upper metallization layers may be formed over the structures shown in FIG. 5.

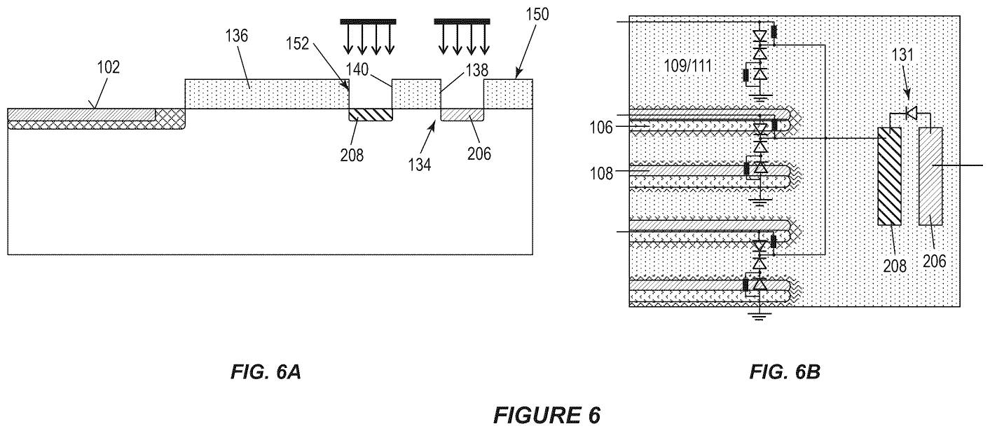

Referring FIG. 6, an exemplary process for forming trigger regions 132 using a hardmask 136 is shown, according to an embodiment. In this case, the ESD protection device 100 is configured such that the trigger device 131 is disposed outside of the rows of doped wells 109,111, as schematically illustrated in FIG. 6B. As shown in FIG. 6A, the hardmask 136 is formed as a continuous structure over the upper surface 102 of the semiconductor body 104 and used as an implantation mask for forming p-type wells 206 and n-type wells 208. The hardmask 136 is patterned to comprise first and second openings 150, 152 that define the geometry of the p-type wells 206 and the n-type wells 208, respectively. Optionally, thin layers of oxide/nitride (now shown) may remain on the upper surface 102 of the semiconductor body 104 to improve diffusion/scattering during the implantation process. A section of the hardmask 136 in between the first and second openings 150, 152 comprises the first outer edge side 138 and the second outer edge side 140 that defines the width of the low-doped section 134 of the semiconductor body 104.

Once the single hard mask is formed, first and second implantation processes are performed to create the p-type wells 206 and the n-type wells 208, respectively. According to the first implantation process, dopant atoms which form p-type impurities in the semiconductor body 104 are implanted into the upper surface 102 through the first openings 150. In an embodiment, the first implantation process comprises implanting BF atoms at a dopant density in the range of 10¹⁵-10¹⁶ atoms/cm² and an implantation energy in the range of 10-20 KeV. According to the second implantation process, dopant atoms which form n-type impurities in the semiconductor body 104 are implanted into the upper surface 102 through the second openings 152. In an embodiment, the second masked implantation technique comprises implanting As atoms at a dopant density in the range of 10¹⁵-10¹⁶ dopant atoms/cm² and an implantation energy in the range of 100-120 KeV.

In addition to the ESD protection device 100 described above, the concepts described herein, and in particular the usage of a hardmask 136 to define the boundaries of a trigger region, may be incorporated into a variety of different ESD protection devices. These ESD protection devices include unidirectional devices, and p-i-n diodes, for example. In one particular example, the second and fourth shallow doped zones 126, 130 may be omitted from the device. In another example, the ESD protection device may be configured as a vertical device, i.e., a device that conducts/blocks in a vertical direction that is perpendicular to a main surface of the semiconductor body. Particularly, the ESD protection device may comprise an active area with any one of the above-mentioned rectifier arrangements, e.g., thyristor, PNPN structure, etc. arranged as a vertical device. Additionally, the ESD protection device may comprise a trigger region adjacent to the active area with a trigger device, e.g., in a similar manner as described with reference to FIG. 6. This trigger region may be created in a similar manner as described above.

Although the present disclosure is not so limited, the following numbered examples demonstrate one or more aspects of the disclosure.

Example 1. A method of forming a semiconductor device, the method comprising: forming a row of n-type wells and p-type wells in an upper surface of a semiconductor body, the p-type wells arranged alternatingly with the n-type wells along a first direction of the semiconductor body; forming trigger regions in between the n-type wells and the p-type wells, the trigger regions comprising a low-doped section of the semiconductor body that is configured to induce current flow between the n-type wells and the p-type wells via avalanche breakdown, wherein the p-type wells and the n-type wells are formed by implanting dopant atoms into the upper surface of the semiconductor body, and wherein the low-doped section of the semiconductor body is formed by a hardmask that prevents the dopant atoms from penetrating the upper surface of the semiconductor body during the implanting of the dopant atoms.

Example 2. The method of example 1, wherein the hardmask comprises a first outer edge side and a second outer edge side opposite from the first outer edge side, and wherein a width of the hardmask between the first and second outer edge sides determines a separation distance between one of the p-type wells and one of the n-type wells in the trigger regions.

Example 3. The method of example 2, wherein the p-type wells and the n-type wells are formed by implanting the dopant atoms through one or more structured photomasks, and wherein the one or more structured photomasks are formed to overlap with the hardmask such that the first outer edge side is exposed by a first opening in the one or more structured photomasks and such that the second outer edge side is exposed by a second opening in the one or more structured photomasks.

Example 4. The method of example 2, wherein the hardmask is a continuous structure that comprises first and second openings, and wherein the p-type wells and the n-type wells are formed by implanting the dopant atoms through the first and second openings, respectively.

Example 5. The method of example 2, wherein forming the hardmask comprises depositing hardmask material on the upper surface of the semiconductor body and subsequently etching the hardmask material to define the first and second outer edge sides.

Example 6. The method of example 1, wherein forming the hardmask comprises performing a LOCOS (local oxidation of silicon) process on the upper surface of the semiconductor body.

Example 7. The method of example 1 wherein the hardmask comprises any one or more of: silicon dioxide, silicon nitride, and silicon oxynitride.

Example 8. The method of example 1, further comprising forming first and second shallow doped zones within the n-type wells and forming third and fourth shallow doped zones within the p-type wells, wherein the first and second shallow doped zones have an opposite conductivity type from one another, wherein the third and fourth shallow doped zones have an opposite conductivity type from one another.

Example 9. The method of example 8, further comprising forming an electrical interconnect structure on the semiconductor body that comprises conductive runners that extend over each of the n-type wells and contact the first and second shallow doped zones and conductive runners that extend over each of the p-type wells and contact the third and fourth shallow doped zones.

Example 10. The method of example 1, wherein the semiconductor device is configured as a silicon-controlled rectifier device.

Example 11. A semiconductor device, comprising: a row of n-type wells and p-type wells in an upper surface of a semiconductor body, the p-type wells arranged alternatingly with the n-type wells along a first direction of the semiconductor body; trigger regions in between the n-type wells and the p-type wells, the trigger regions comprising a low-doped section of the semiconductor body that is configured to induce current flow between the p-type wells and the n-type wells via avalanche breakdown; and hardmasks disposed over the low-doped sections of the semiconductor body, wherein the hardmasks comprise a first outer edge side and a second outer edge side opposite from the first outer edge side, wherein outer boundaries of the p-type wells are aligned with the first outer edge side the hardmasks, and wherein outer boundaries of the n-type wells are aligned with the second outer edge side the hardmasks.

Example 12. The semiconductor device of example 11, wherein the hardmasks comprise any one or more of: silicon dioxide, silicon nitride, and silicon oxynitride.

Example 13. The semiconductor device of example 11, wherein the hardmasks are disposed completely above the semiconductor body.

Example 14. The semiconductor device of example 11, wherein the hardmasks comprise a locally oxidized portion of the semiconductor body.

Example 15. The semiconductor device of example 11, further comprising first and second shallow doped zones within the n-type wells and third and fourth shallow doped zones within the p-type wells, wherein the first and second shallow doped zones have an opposite conductivity type from one another, and wherein the third and fourth shallow doped zones have an opposite conductivity type from one another.

Example 16. The semiconductor device of example 15, further comprising an electrical interconnect structure on the semiconductor body that comprises conductive runners that extend over each of the n-type wells and contact the first and second shallow doped zones and conductive runners that extend over each of the p-type wells and contact the third and fourth shallow doped zones.

Example 17. The semiconductor device of example 11, wherein the semiconductor device is configured as a silicon-controlled rectifier device.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

Notably, modifications and other embodiments of the disclosed invention(s) will come to mind to one skilled in the art having the benefit of the teachings presented in the foregoing descriptions and the associated drawings. Therefore, it is to be understood that the invention(s) is/are not to be limited to the specific embodiments disclosed and that modifications and other embodiments are intended to be included within the scope of this disclosure. Although specific terms may be employed herein, they are used in a generic and descriptive sense only and not for purposes of limitation

With the above range of variations and applications in mind, it should be understood that the present invention is not limited by the foregoing description, nor is it limited by the accompanying drawings. Instead, the present invention is limited only by the following claims and their legal equivalents.

1. A method of forming a semiconductor device, the method comprising:
forming a row of n-type wells and p-type wells in an upper surface of a semiconductor body, the p-type wells arranged alternatingly with the n-type wells along a first direction of the semiconductor body; and
forming trigger regions in between the n-type wells and the p-type wells, the trigger regions comprising a low-doped section of the semiconductor body that is configured to induce current flow between the p-type wells and the n-type wells via avalanche breakdown,
wherein the p-type wells and the n-type wells are formed by implanting dopant atoms into the upper surface of the semiconductor body, and
wherein the low-doped section of the semiconductor body is formed by a hardmask that prevents the dopant atoms from penetrating the upper surface of the semiconductor body during the implanting of the dopant atoms.

2. The method of claim 1, wherein the hardmask comprises a first outer edge side and a second outer edge side opposite from the first outer edge side, and wherein a width of the hardmask between the first and second outer edge sides determines a separation distance between one of the p-type wells and one of the n-type wells in the trigger regions.

3. The method of claim 2, wherein the p-type wells and the n-type wells are formed by implanting the dopant atoms through one or more structured photomasks, and wherein the one or more structured photomasks are formed to overlap with the hardmask such that the first outer edge side is exposed by a first opening in the one or more structured photomasks and such that the second outer edge side is exposed by a second opening in the one or more structured photomasks.

4. The method of claim 2, wherein the hardmask is a continuous structure that comprises first and second openings, and wherein the p-type wells and the n-type wells are formed by implanting the dopant atoms through the first and second openings, respectively.

5. The method of claim 2, wherein forming the hardmask comprises depositing hardmask material on the upper surface of the semiconductor body and subsequently etching the hardmask material to define the first and second outer edge sides.

6. The method of claim 1, wherein forming the hardmask comprises performing a LOCOS (local oxidation of silicon) process on the upper surface of the semiconductor body.

7. The method of claim 1 wherein the hardmask comprises any one or more of: silicon dioxide, silicon nitride, and silicon oxynitride.

8. The method of claim 1, further comprising forming first and second shallow doped zones within the n-type wells and forming third and fourth shallow doped zones within the p-type wells, wherein the first and second shallow doped zones have an opposite conductivity type from one another, wherein the third and fourth shallow doped zones have an opposite conductivity type from one another.

9. The method of claim 8, further comprising forming an electrical interconnect structure on the semiconductor body that comprises conductive runners that extend over each of the n-type wells and contact the first and second shallow doped zones and comprises conductive runners that extend over each of the p-type wells and contact the third and fourth shallow doped zones.

10. The method of claim 1, wherein the semiconductor device is configured as a silicon-controlled rectifier device.

11. A semiconductor device, comprising:
a row of n-type wells and p-type wells in an upper surface of a semiconductor body, the p-type wells arranged alternatingly with the n-type wells along a first direction of the semiconductor body; and
trigger regions in between the n-type wells and the p-type wells, the trigger regions comprising a low-doped section of the semiconductor body that is configured to induce current flow between the p-type wells and the n-type wells via avalanche breakdown; and
hardmasks disposed over the low-doped sections of the semiconductor body,
wherein the hardmasks comprise a first outer edge side and a second outer edge side opposite from the first outer edge side,
wherein outer boundaries of the p-type wells are aligned with the first outer edge side the hardmasks, and
wherein outer boundaries of the n-type wells are aligned with the second outer edge side the hardmasks.

12. The semiconductor device of claim 11, wherein the hardmasks comprise any one or more of: silicon dioxide, silicon nitride, and silicon oxynitride.

13. The semiconductor device of claim 11, wherein the hardmasks are disposed completely above the semiconductor body.

14. The semiconductor device of claim 11, wherein the hardmasks comprise a locally oxidized portion of the semiconductor body.

15. The semiconductor device of claim 11, further comprising first and second shallow doped zones within the n-type wells and third and fourth shallow doped zones within the p-type wells, wherein the first and second shallow doped zones have an opposite conductivity type from one another, and wherein the third and fourth shallow doped zones have an opposite conductivity type from one another.

16. The semiconductor device of claim 15, further comprising an electrical interconnect structure on the semiconductor body that comprises conductive runners that extend over each of the n-type wells and contact the first and second shallow doped zones and conductive runners that extend over each of the p-type wells and contact the third and fourth shallow doped zones.

17. The semiconductor device of claim 11, wherein the semiconductor device is configured as a silicon-controlled rectifier device.
